(19) United States
(12) Patent Application Publication
(10) Pub. No.: US 2013/0068285 A1
(43) Pub. Date: Mar. 21, 2013

(54) METHOD AND DEVICE FOR TWO-STAGE SOLAR CONCENTRATION AND SPECTRUM SPLITTING BASED ON DISH CONCENTRATION

(71) Applicants: Mingjiang Ni, Hangzhou (CN); Gang Xiao, Hangzhou (CN); Zhongyang Luo, Hangzhou (CN); Kefa Cen, Hangzhou (CN); Xiang Gao, Hangzhou (CN); Mengxiang Fang, Hangzhou (CN); Jinsong Zhou, Hangzhou (CN); Zhenglun Shi, Hangzhou (CN); Leming Cheng, Hangzhou (CN); Qinhui Wang, Hangzhou (CN); Shurong Wang, Hangzhou (CN); Chunjiang Yu, Hangzhou (CN)

(72) Inventors: Mingjiang Ni, Hangzhou (CN); Gang Xiao, Hangzhou (CN); Zhongyang Luo, Hangzhou (CN); Kefa Cen, Hangzhou (CN); Xiang Gao, Hangzhou (CN); Mengxiang Fang, Hangzhou (CN); Jinsong Zhou, Hangzhou (CN); Zhenglun Shi, Hangzhou (CN); Leming Cheng, Hangzhou (CN); Qinhui Wang, Hangzhou (CN); Shurong Wang, Hangzhou (CN); Chunjiang Yu, Hangzhou (CN)

(73) Assignee: ZHEJIANG UNIVERSITY, HANGZHOU, Zhejiang Province (CN)

(21) Appl. No.: 13/699,859

(22) PCT Filed: Jun. 30, 2011
(86) PCT No.: PCT/CN2011/076602

§ 371 Date: Nov. 26, 2012

(30) Foreign Application Priority Data
Feb. 25, 2011 (CN) 201110045294.6

(51) Int. Cl. H01L 31/058; F24J 2/12; F24J 2/38; F24J 2/08

(52) U.S. Cl. CPC H01L 31/058; F24J 2/08; F24J 2/12; F24J 2/38
USPC 136/248; 126/690; 126/714; 126/600

(57) ABSTRACT

The present invention discloses a method and device for two-stage solar concentration and a spectrum splitting dish reflector based on dish concentration. A parabolic dish reflector is provided with a central light hole. A CPV panel and a solar-to-heat receiver are positioned at the two sides of the axial line of dish reflector, respectively, under the light hole. A splitting lens is placed at a certain distance from the apex of dish reflector over the light hole. The splitting film is applied to the curved surface of the lens near the parabolic dish, as a spectrum splitting surface. The curved surface of the lens far from the parabolic dish is covered by silver, as a reflecting surface. A supporting structure is provided between the dish reflector and the splitting lens. The whole system with a dual-axis tracking system is placed on the foundation of a support. The present invention can simultaneously realize solar energy concentration and spectrum splitting, to obtain two concentrated spots of different spectrums under the system, which can effectively reduce energy consumption of tracking system and improve system balance and wind resistance. The present invention can adjust the concentration ratio of two beams individually to satisfy the optimal concentrating intensity needed by the CPV panel and the solar-to-heat receiver.

### FIELD OF THE INVENTION

The present invention relates to the field of using solar to generate power, and more specially relates to a method and device for two-stage solar concentration and spectrum splitting.

### DESCRIPTION OF THE PRIOR ART

The global solar radiation amount is about 1.7×10¹⁷ W, among which China holds about 1% (1.8×10¹⁵ W, equivalent to 1,900,000 million tons of standard coal per year), which is 680 times of the annual energy consumption in the whole country. Electricity is the largest secondary energy consumed in the world. The technology to use solar energy generating power is the effective way to relieve current energy crises and has a broad perspective in application.

Solar power technology is mainly divided into two types: photovoltaic (PV) and solar thermal power (STP) technology. PV power technology makes use of photovoltaic effect of photovoltaic panel to generate electricity. This technology has three main shortcomings: (1) the generated output changes with solar intensity, and none of output is generated at night or on rainy day, producing a large impact on power grid; (2) the solar flux density is low and large area of photovoltaic panel is needed for unit power generation capacity. Manufacturing PV panels cause serious pollution and incur high cost; (3) the response wave bands of PV panel to solar spectrum are mainly concentrated in high frequency area (400<λ<1100 nm). Most of the energy in low frequency area is converted to heat to raise the temperature of PV panel, lower their photo-electric conversion efficiency and shorten their service life. Concentrated Photovoltaic (CPV) method for power generation can significantly reduce the use area of PV panel. Thin film splitting method for power generation can first split low frequency wave in sunlight and then the rest of the sunlight (400<λ<1100 nm) illuminates PV panel. These are two important directions of PV technology. As to the discontinuity of solar radiation, PV technology can only rely on expensive supplementary accumulator battery or energy-storage generating system (such as pumped storage hydroelectric power station). The cost is high.

STP makes use of reflectors (or Fresnel lens) to concentrate sunlight, by photothermal conversion and heat exchanger to produce vapor or by heating fluid to drive a generator (such as a steam turbine or a Stirling engine) to generate electricity. The advantages of STP are to attract all wave-band sunlight and continuously generate electricity day and night. Reflectors mainly consist of three types: the trough type, tower type and dish type. The trough reflector concentrates sunlight in a line parallel to the reflecting surface. This technology can only realize one dimensional trace of the sun light, providing a low rate of solar utilization. The tower concentration usually makes use of thousands (or more) of heliostats to concentrate sunlight on a solar-to-heat receiver on the top of a high tower. This system occupies a large area and the orientation of every heliostat is different, which requires a complicated control system. The dish concentration reflector usually consists of an integral rotary parabolic mirror or multi-mirrors, and is able to concentrate sunlight on a small area with a flexible adjustable ratio between occupied area and concentration. Therefore, dish concentration is an important aspect to be developed. Current dish concentration power system requires the installation of a Stirling engine on the focus of the dish reflector. The heavy weight of the Stirling engine increases tracking energy consumption and markedly reduces system balance and wind resistance.

From the view of current technology, the peak efficiency of either CPV or Dish concentrated solar power (CSP) technology can reach about 30%. If it is possible to make use of the method of concentration and spectrum splitting to combine CPV (utilizing high-frequency) with dish CSP (utilizing low-frequency), one can achieve continuous electricity generation day and night with a peak efficiency of about 40%. If it is possible to obtain the concentrated focal spots under the system or on the ground, one can efficiently reduce energy consumption of system and improve system balance and wind resistance.

Although current trough, tower and dish concentrating systems have their own method of splitting, their common shortcoming is as follows. Because of simply using splitting film to split solar spectrum and the two beams locating at different sides of the splitter, the two focuses cannot be under the system or on the ground at the same time and the concentration ratios cannot be adjusted, thus reducing the feasibility and flexibility of CPV-CSP hybrid power system.

### SUMMARY OF THE INVENTION

The object of the present invention is to overcome the shortcoming of current concentration and spectrum splitting system by providing a method and device for two-stage solar concentration and spectrum splitting based on dish concentration.

The method for two-stage solar concentration and spectrum splitting based on dish concentration is as follows. The method uses a rotary parabolic dish to concentrate sunlight, place a splitting lens at 200˜4000 mm from the apex of the parabolic dish, adhere a splitting film on the curved surface of splitting lens near the parabolic dish, reflect the sunlight in the range of CPV panel response wave band to the CPV panel through a light hole. The silver covered surface—the other curved surface of splitting lens far from the parabolic dish—reflects the light passing through the splitting film and reaching the solar-to-heat receiver through the light hole.

The dish reflector of rotary parabolic surface in the device for two-stage solar concentration and spectrum splitting based on dish concentration is provided with a central light hole. A CPV panel and a solar-to-heat receiver are positioned at both sides of the axial line of parabolic dish under the light hole. A splitting lens is placed at 200˜4000 mm from the apex of the parabolic dish over the light hole. The splitting lens is provided with two different curved surfaces. A splitting film is applied to the curved surface of splitting lens near the parabolic dish. Another curved surface of the lens far from the parabolic dish is covered by silver, as a reflecting surface. A supporting structure is provided between the parabolic dish and the splitting lens. The ring truss of parabolic dish is connected to one end of a pedestal through dual-axis tracking system. The dish controller of dual-axis tracking system is placed on the ground with the other end connected to its foundation.

The layout of said splitting lens is as follows: splitting lens is placed between the parabolic dish and its concentrating focus, or on the outside of the focus of the parabolic dish, or two different curved surfaces of splitting lens placed on the inside and outside of the focus of the parabolic dish. When the splitting lens is placed between parabolic dish and its concentrating focus, both curved surfaces of splitting lens are convex camber surfaces and the perifocuses of two curved surfaces are on the two sides of the axial line of the parabolic dish, respectively. The surface equation of the convex camber surfaces is one or more revolving hyperbolic equations. When the splitting lens is placed on the outside of the focus of parabolic dish, its concentrating focus, both curved surfaces of splitting lens are concave camber surfaces and the perifocuses of two curved surfaces are on the two sides of the axial line of the parabolic dish, respectively. The surface equation of the concave camber surfaces is one or more revolving elliptic equations. When two different curved surfaces of said splitting lens are placed on the inside and outside of the focus of the parabolic dish, respectively, the two different curved surfaces of said splitting lens are revolving hyperbolic convex camber surfaces and revolving elliptic concave camber surfaces. The concave camber surface is between the parabolic dish and its focus, while the concave camber surface is on the outside of the focus of the parabolic dish. The perifocuses of convex camber surface and concave camber surface are on the same side of axial line of the parabolic dish, respectively. The surface equation of the convex camber surfaces is one or more revolving hyperbolic equations. The surface equation of the concave camber surfaces is one or more revolving elliptic equations.

In comparison with prior art, the present invention has the following technical benefits:

1. The method of the present invention can simultaneously realize the concentration and splitting of solar energy and obtain two concentrating spots under the system, thus effectively reducing the energy consumption of tracking system and improving system balance and wind resistance.

2. The method of the present invention can adjust the concentration ratio of two beams by adjusting the equations of two different curved surfaces of splitting lens, thus satisfying the optical concentrating intensity needed by the CPV panel and solar-to-heat receiver (or heater head of Stirling engine), respectively.

### BRIEF DESCRIPTION OF THE DRAWINGS

FIG. 1 is a schematic view of the method for two-stage solar concentration and spectrum splitting based on dish concentration;

FIG. 2 is a schematic view of splitting lens with two different curved surfaces between the dish reflector and its focus of the present invention;

FIG. 3 is a schematic view of splitting lens with two different curved surfaces on the outside of the focus of dish reflector of the present invention; and

FIG. 4 is a schematic view of splitting lens with two different curved surfaces, respectively, on the inside and outside of the focus of dish reflector of the present invention.

In the figures: dish controller 1, parabolic dish 2, light hole 3, supporting structure 4, silver covered surface 5, splitting lens 6, splitting film 7, solar-to-heat receiver 8, CPV panel 9, ring truss 10, dual-axis tracking system 11, pedestal 12, foundation 13

### DETAILED DESCRIPTION OF THE PREFERRED EMBODIMENTS

The method for two-stage solar concentration and spectrum splitting based on dish concentration is as follows. The method uses a parabolic dish 2 with a central light hole 3 to concentrate sunlight, and place a splitting lens 6 at 200˜4000 mm from the apex of the parabolic dish 2. Said splitting lens 6 is provided with two different curved surfaces. A splitting film 7 is attached to the curved surface of the splitting lens 6 near the parabolic dish 2, reflecting the sunlight in the range of response wave band of CPV panel 9 to CPV panel 9 through the light hole 3. The silver covered surface 5—the other curved surface of splitting lens 6 far from the parabolic dish 2—reflects the light passing through the splitting film 7 to the solar-to-heat receiver 8 through the light hole 3.

The layout of said splitting lens 6 is as follows. The splitting lens 6 is placed between the parabolic dish 2 and its concentrating focus, or on the outside of the focus of the parabolic dish 2, or two different curved surfaces of the splitting lens 6 placed on the inside and outside of the focus of the parabolic dish 2. When the splitting lens 6 is placed between the parabolic dish 2 and its concentrating focus, both curved surfaces of splitting lens 6 are revolving the hyperbolic convex camber surfaces and the perifocuses of two curved surfaces are on the two sides of the axial line of the parabolic dish 2, respectively. The surface equation of the convex camber surfaces is one or more revolving hyperbolic equations. When the splitting lens 6 is placed on the outside of its concentrating focus of the parabolic dish 2, two different curved surfaces of splitting lens 6 are revolving elliptic concave camber surfaces and the perifocuses of two curved surfaces are on the two sides of the axial line of the parabolic dish 2, respectively. The surface equation of the concave camber surfaces is one or more revolving elliptic equations. When two different curved surfaces of said splitting lens 6 are placed on the inside and outside of the focus of the parabolic dish 2, respectively, the two different curved surfaces of said splitting lens 6 are revolving hyperbolic convex camber surfaces and revolving elliptic concave camber surfaces, respectively. The concave camber surface is between the parabolic dish 2 and its focus, while the concave camber surface is on the outside of the focus of the parabolic dish 2. The perifocuses of convex camber surface and concave camber surface are on the same side of axial line of the parabolic dish 2, respectively. The surface equation of the convex camber surfaces is one or more revolving hyperbolic equations. The surface equation of the concave camber surfaces is one or more revolving elliptic equations.

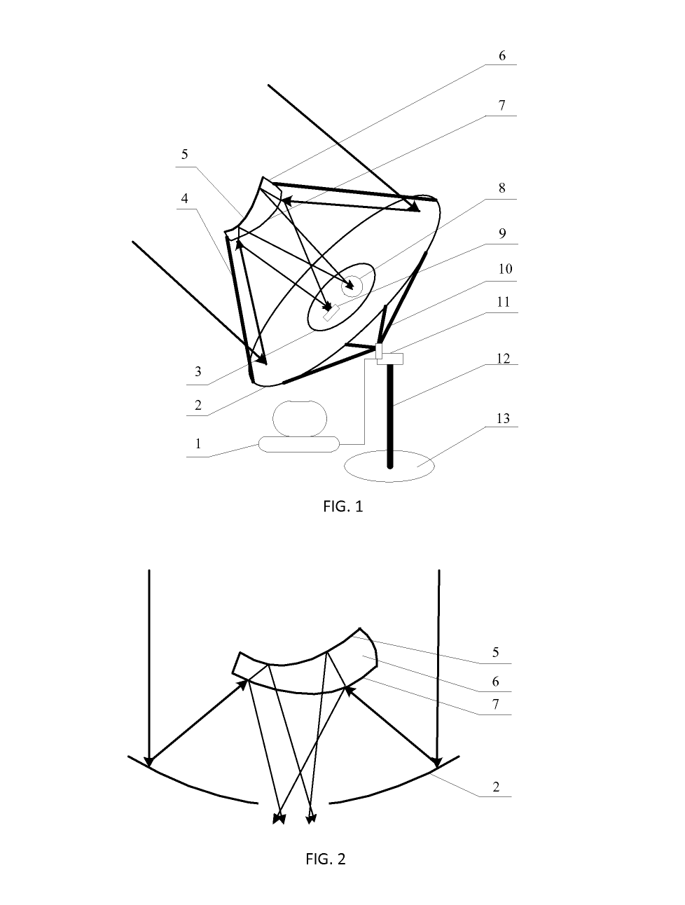

As shown in FIG. 1, the device for two-stage solar concentration and spectrum splitting based on dish concentration consists of a dish controller 1, a parabolic dish 2, a light hole 3, a supporting structure 4, a silver covered surface 5, a splitting lens 6, a splitting film 7, a solar-to-heat receiver 8, a CPV panel 9, a ring truss 10, a dual-axis tracking system 11, a pedestal 12, and a foundation 13. The dish reflector 2 of rotary parabolic surface in the device for two-stage solar concentration and spectrum splitting based on dish concentration is provided with a central light hole 3. The CPV panel 9 and the solar-to-heat receiver 8 are positioned at the two sides of the axial line of the parabolic dish 2, respectively, under the light hole 3. The splitting lens 6 is placed at 200˜4000 mm from the apex of the parabolic dish 2 over the light hole 3. The splitting lens 6 is provided with two different curved surfaces. The splitting film 7 is applied to the curved surface of splitting lens near the parabolic dish 2. Another curved surface of the splitting lens far from the parabolic dish 2 is silver covered surface 5. The supporting structure 4 is provided between the parabolic dish 2 and the splitting lens 6. The ring truss 10 of the parabolic dish 2 is connected to one end of the pedestal 12 through dual-axis tracking system 11. The dish controller 1 of dual-axis tracking system 11 is placed on the ground with the other end connected to its foundation.

The layout of said splitting lens 6 is as follows. The splitting lens 6 is placed between the parabolic dish 2 and its concentrating focus, or on the outside of the focus of the parabolic dish 2, or two different curved surfaces of the splitting lens 6 placed on the inside and outside of the focus of the parabolic dish 2.

As shown in FIG. 2, when the splitting lens 6 is placed between the parabolic dish 2 and its concentrating focus, both curved surfaces of the splitting lens 6 are convex camber surfaces and the perifocuses of two curved surfaces are on the two sides of the axial line of the parabolic dish 2, respectively. The curved surface equation of said convex camber surfaces is one or more revolving hyperbolic curve equations. The splitting film 7 is applied to the convex camber surface near the parabolic dish 2. The other convex camber surface far from the parabolic dish 2 is silver covered surface 5.

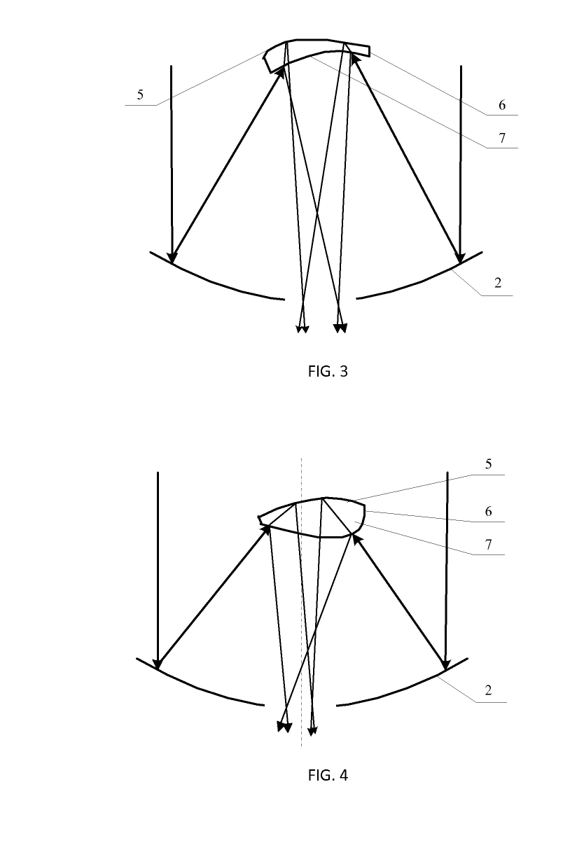

As shown in FIG. 3, when the splitting lens 6 is placed on the outside of concentrating focus of the parabolic dish 2, both curved surfaces of splitting lens 6 are concave camber surfaces and the perifocuses of two curved surfaces are on the two sides of the axial line of the parabolic dish 2, respectively. The curved surface equation of said concave camber surfaces is one or more revolving elliptic equations. The splitting film 7 is applied to the concave camber surface near the parabolic dish 2. The other convex camber surface far from parabolic dish 2 is silver covered surface 5.

As shown in FIG. 4, when two different curved surfaces of said splitting lens 6 are placed on the inside and outside of the focus of the parabolic dish 2, respectively, the two different curved surfaces of said splitting lens 6 are convex camber surfaces and concave camber surfaces, respectively. The concave camber surface is between the parabolic dish 2 and its focus, while the concave camber surface is on the outside of the focus of the parabolic dish 2. The perifocuses of revolving hyperbolic convex camber surface and revolving elliptic concave camber surface are on the same side of axial line of the parabolic dish 2, respectively. The surface equation of the convex camber surfaces is one or more revolving hyperbolic equations. The surface equation of the concave camber surfaces is one or more revolving elliptic equations. Splitting film 7 is applied to the convex camber surface near the parabolic dish 2. The other convex camber surface far from the parabolic dish 2 is silver covered surface 5.

### EXAMPLES

The apex of rotary parabolic reflecting surface is set as the initial point and the horizontal plane is set as the XY plane. The axis vertical to the plane is set as Z axis (Z>0). The parabolic dish has a diameter of 3500 mm and the opening of light hole has a diameter of 600 mm. The standard equation of the parabolic dish can be written as X²+Y²=6062Z. Splitting lens with a diameter of 600 mm is placed right over the central axial line of parabolic dish. The vertical distance between the center of splitting lens and the initial point is 1265 mm. The curve with splitting film will rotate 4.6° around the coordinate system, so that when the central axial line coincides with the central axial line of the parabolic dish, the standard equation of the hyperboloid can be written as

$$\frac{{Z}^{2}}{{663}^{2}} - \frac{{X}^{2} + {Y}^{2}}{{660}^{2}} = 1.$$

The silver covered surface will rotate 4.6° in a reverse direction around the coordinate system, so that when the central axial line coincides with the central axial line of the parabolic dish, the standard equation of the hyperboloid can be written as

$$\frac{{Z}^{2}}{{707}^{2}} - \frac{{X}^{2} + {Y}^{2}}{{613}^{2}} = 1.$$

CPV panel and solar-to-heat receiver are placed at 700 mm and 350 mm under the parabolic dish, respectively.

In a sunny morning in spring season in eastern China, the light spot on CPV panel has a diameter of 200 mm and mean energy flux density is 70-80 kW/m². The light spot at the solar-to-heat receiver has a diameter of about 100 mm and mean energy flux density is 300-400 kW/m².

At a sunny noon in summer season in eastern China, the light spot on CPV panel has a diameter of 200 mm and mean energy flux density is 90-100 kW/m². The light spot at the solar-to-heat receiver has a diameter of about 100 mm and mean energy flux density is 500-600 kW/m².

At a sunny noon in autumn season in eastern China, the light spot on CPV panel has a diameter of 200 mm and mean energy flux density is 70-80 kW/m². The light spot at the solar-to-heat receiver has a diameter of about 100 mm and mean energy flux density is 300-400 kW/m².

At a sunny afternoon in winter season in eastern China, the light spot on CPV panel has a diameter of 200 mm and mean energy flux density is 50-60 kW/m². The light spot at the solar-to-heat receiver has a diameter of about 100 mm and mean energy flux density is 200-250 kW/m².

1. A method for two-stage solar concentration and spectrum splitting based on dish concentration, comprising the steps of: using a parabolic dish reflector (2) with a central light hole (3) to concentrate the sunlight, placing a splitting lens (6) at 200˜4000 mm from an apex of the parabolic dish reflector (2), said splitting lens (6) being provided with two different curved surfaces, a splitting film (7) applied on the curved surface of splitting lens (6) near the parabolic dish reflector (2) to reflect the sunlight in a range of response wave band of a concentrated photovoltaic panel (9) through the light hole (3) to the concentrated photovoltaic panel, the other curved surface of splitting lens (6) far from the parabolic dish reflector (2) being a silver covered surface (5), the silver covered surface (5) reflecting the light passing through the splitting film (7), and reaching a solar-to-heat receiver (8) through the light hole (3).

2. The method for two-stage solar concentration and spectrum splitting based on dish concentration as set forth in claim 1, wherein the splitting lens (6) is placed between the parabolic dish reflector (2) and its concentrating focus, or the splitting lens (6) is placed on an outside of a focal spot of the parabolic dish reflector (2), or two different curved surfaces of the splitting lens (6) are placed on the inside and outside of the focus of the parabolic dish reflector (2), respectively.

3. The method for two-stage solar concentration and spectrum splitting based on dish concentration as set forth in claim 2, wherein when the splitting lens (6) is placed between the parabolic dish reflector (2) and its concentrating focus; two different curved surfaces of splitting lens (6) are convex camber surfaces, perifocuses of the two convex camber surfaces are located on two sides of the axial line of the parabolic dish reflector (2), respectively; surface equation of the convex camber surfaces is one or more revolving hyperbolic equations.

4. The method for two-stage solar concentration spectrum splitting based on dish concentration as set forth in claim 2, wherein when the splitting lens (6) is placed on the outside of the focal spot of parabolic dish reflector (2), two different curved surfaces of the splitting lens (6) are concave camber surfaces and the perifocuses of two curved surfaces are on the two sides of the axial line of parabolic dish reflector (2), respectively; surface equation of the concave camber surfaces is one or more revolving elliptic equations.

5. The method for two-stage solar concentration and spectrum splitting based on dish concentration as set forth in claim 2, wherein when two different curved surfaces of the splitting lens (6) are placed on inside and outside of the focus of the parabolic dish reflector (2), respectively, the two different curved surfaces of the splitting lens (6) are convex camber surfaces and concave camber surfaces, respectively; the concave camber surface is between parabolic dish reflector (2) and its focus, while the concave camber surface is on the outside of the focus of parabolic dish (2); the perifocuses of convex camber surface and concave camber surface are on the same side of axial line of parabolic dish reflector (2), respectively; surface equation of the convex camber surfaces is one or more revolving hyperbolic equations and surface equation of the concave camber surfaces is one or more revolving elliptic equations.

6. The device for two-stage solar concentration and spectrum splitting based on dish concentrations set forth in claim 1, wherein parabolic dish reflector (2) is provided with a central light hole (3); a CPV panel (9) and a solar-to-heat receiver (8) are positioned at two sides of an axial line of the parabolic dish reflector (2) under the light hole (3); a splitting lens (6) is placed at 200˜4000 mm from an apex of the parabolic dish reflector (2) over the light hole (3), the splitting lens (6) is provided with two different curved surfaces; a splitting film (7) is applied to the curved surface of the lens near the parabolic dish reflector (2), as a spectrum splitting surface; the curved surface of the lens far from the parabolic dish reflector (2) is covered by silver, as a reflecting surface (5); a supporting structure (4) is provided between the parabolic dish reflector (2) and the splitting lens (6); a ring truss (10) of parabolic dish reflector (2) is connected to one end of a pedestal (12) through a dual-axis tracking system (11); a dish controller (1) of the dual-axis tracking system (11) is placed on the ground and the other end of the pedestal (12) is connected to a foundation (13).

7. The device for two-stage solar concentration and spectrum splitting based on dish concentration as set forth in claim 6, wherein the splitting lens (6) is placed between the parabolic dish reflector (2) and its concentrating focus, or on the outside of a focal spot of the parabolic dish reflector (2), or two different curved surfaces of the splitting lens (6) placed on the inside and outside of the focus of the parabolic dish reflector (2), respectively.

8. The device for two-stage solar concentration and spectrum splitting based on dish concentration as set forth in claim 6, wherein when the splitting lens (6) is placed between the parabolic dish reflector (2) and its concentrating focus, two different curved surfaces of the splitting lens (6) are convex camber surfaces and the perifocuses of two curved surfaces are on the two sides of the axial line of parabolic dish reflector (2), respectively; surface equation of the convex camber surfaces is one or more revolving hyperbolic equations.

9. The device for two-stage solar concentration spectrum splitting based on dish concentration as set forth in claim 6, wherein when the splitting lens (6) is placed on the outside of focal spot of parabolic dish reflector (2), two different curved surfaces of splitting lens (6) are concave camber surfaces and the perifocuses of two curved surfaces are on the two sides of the axial line of parabolic dish reflector (2), respectively; surface equation of the concave camber surfaces is one or more revolving elliptic equations.

10. The device for two-stage solar concentration and spectrum splitting based on dish concentration as set forth in claim 6, wherein when two different curved surfaces of the splitting lens (6) are placed on the inside and outside of the focus of parabolic dish reflector (2), respectively, the two different curved surfaces of the splitting lens (6) are convex camber surfaces and concave camber surfaces, respectively; the concave camber surface is between parabolic dish reflector (2) and its focus, while the concave camber surface is on the outside of the focus of parabolic dish reflector (2); the perifocuses of convex camber surface and concave camber surface are on the same side of axial line of parabolic dish reflector (2), respectively; surface equation of the convex camber surfaces is one or more revolving hyperbolic equations and surface equation of the concave camber surfaces is one or more revolving elliptic equations.
